(19) United States
(12) Patent Application Publication
(10) Pub. No.: US 2011/0100556 A1
(43) Pub. Date: May 5, 2011

(54) Plasma System with Injection Device

(75) Inventors: Chi-Hung Liu, Taichung County (TW); Chen-Der Tsai, Sinpu Township (TW); Wen-Tung Hsu, Citong Township (TW); Chun-Hsien Su, Hsinchu City (TW); Wen-Chin Cheng, Hsinchu City (TW); Liang-Yi Chen, Jinhu Township (TW)

(73) Assignee: INDUSTRIAL TECHNOLOGY RESEARCH INSTITUTE, Hsinchu (TW)

(21) Appl. No.: 12/647,041

(22) Filed: Dec. 24, 2009

(30) Foreign Application Priority Data
Nov. 2, 2009 (TW) 98137165

(51) Int. Cl. C23F 1/08; C23C 16/00

(52) U.S. Cl. 156/345.43; 118/723 E

(57) ABSTRACT

A plasma system with an injection device is provided. The plasma system comprises a plasma cavity and an injection device. The plasma cavity comprises a first electrode and a second for generating plasma. The injection device comprises a plasma injection tube and at least a reactant injection tube. The plasma injection tube is connected to the plasma cavity. The plasma injection tube comprises an inlet, an outlet and an outer sidewall. The plasma injection tube injects the plasma from the inlet and guides the plasma out through the outlet. The outer sidewall has a width decreasing from the inlet to the outlet. The reactant injection tube is disposed outside of the outer sidewall. The reactant injection tube injects a reactant to the outer sidewall so that the reactant flows along the outer sidewall toward the outlet and mixes with the plasma at the outlet.

This application claims the benefit of Taiwan application Serial No. 98137165, filed Nov. 2, 2009, the subject matter of which is incorporated herein by reference.

### BACKGROUND OF THE INVENTION

1. Field of the Invention

The invention relates in general to a plasma system, and more particularly to a plasma system with an injection device.

2. Description of the Related Art

Plasma technology, which has been developed for several years, uses high-energy particles (electrons and ions) of the plasma and active species to create the effects of plating, etching and surface improvement on the work piece to be processed. Plasmas technology can be applied to the photoelectric and semiconductor industry, 3C products, automobile industry, civil material industry and biomedical material surface processing, etc.

Take plasma plating technology as an example. Mixing the reactant for forming the film with plasma can help to activate the reactant and increase the activity of the substrate surface. Until now, the plasma plating technology has developed several methods for mixing the plasma and reactant. For example, a Japan Patent No. 2000-121804 discloses that plasma is generated through an upper electrode and a lower electrode. The substrate is disposed on the lower electrode. The reactant is injected to the space between the upper and lower electrodes. However, in this mixture method of plasma and reactant, the reactant will easily deposit at the surface of the upper electrode to influence stability of the plasma and result in contamination to the following manufacturing process.

Besides, a European Patent No. 0617142 discloses generation of plasma by using an electrode rod and a circular electrode barrel. The electrode rod is disposed at the center of the electrode barrel. The reactant is injected to the space between the electrode rod and electrode barrel. In this way, the reactant will still deposit at the surface of the electrode rod or electrode barrel.

Furthermore, the journal “APPLIED PHYSICS LETTERS 89. 251504 (2006)” reported a paper “Atmospheric pressure microplasma jet as a depositing tool”, which generates plasma by a small electrode tube and a large electrode tube. The small electrode tube is disposed at the center of the large electrode tube, and the reactant is injected via the small electrode tube into the space between the small and large electrode tubes. Using this method will still cause the deposition of reactant on the surface of the small or large electrode tube.

The above-mentioned patents and journal are aimed at fully mixing the plasma with reactant, which in turn, results in the reactant deposition on the electrode.

In some methods, the reactant can be prevented from depositing on the electrode, but the plasma and the reactant may not be fully mixed, thereby reducing manufacturing efficiency. Therefore, there is no method available to fully mix the plasma and reactant without causing the reactant deposition of the electrode since the plasma technology has been developed until now, which seriously limits the development of plasma technology.

### SUMMARY OF THE INVENTION

The invention is directed to a plasma system with an injection device. By using a suitable structural design, the plasma and reactant can be fully mixed and the reactant can be prevented from depositing on the electrode.

According to an aspect of the present invention, a plasma system is provided. The plasma system comprises a plasma cavity and an injection device. The plasma cavity comprises a first electrode and a second electrode for generating plasma. The injection device comprises a plasma injection tube and at least a reactant injection tube. The plasma injection tube is connected to the plasma cavity. The plasma injection tube comprises an inlet, an outlet and an outer sidewall. The plasma injection tube injects the plasma from the inlet and guides the plasma out through the outlet. The outer sidewall has a width decreasing from the inlet to the outlet. The reactant injection tube is disposed outside of the outer sidewall. The reactant injection tube injects a reactant to the outer sidewall so that the reactant flows along the outer sidewall toward the outlet and mixes with the plasma at the outlet.

The invention will become apparent from the following detailed description of the embodiments. The following description is made with reference to the accompanying drawings.

### BRIEF DESCRIPTION OF THE DRAWINGS

FIG. 1 is a schematic diagram of a plasma system according to an embodiment of the invention.

FIG. 2 is a cross-sectional solid view of the injection device in FIG. 1.

FIG. 3 is a cross-sectional plan view of the injection device in FIG. 1.

FIGS. 4-6 are solid views of the plasma injection tube of FIG. 1.

FIG. 7 is a bottom view of the plasma injection tube of FIG. 6.

FIG. 8 is a schematic diagram of the plasma and reactant mixed in the plasma injection tube under a non-rotating condition.

FIG. 9 is a schematic diagram of the plasma and reactant mixed in the plasma injection tube under a rotating condition.

### DETAILED DESCRIPTION OF THE INVENTION

Detailed descriptions will be given by embodiments in the following. However, the embodiments are taken only for illustration and will not limit the scope of the invention. Besides, the drawings in the embodiments omit unnecessary components in order to clearly show the feature of the invention.

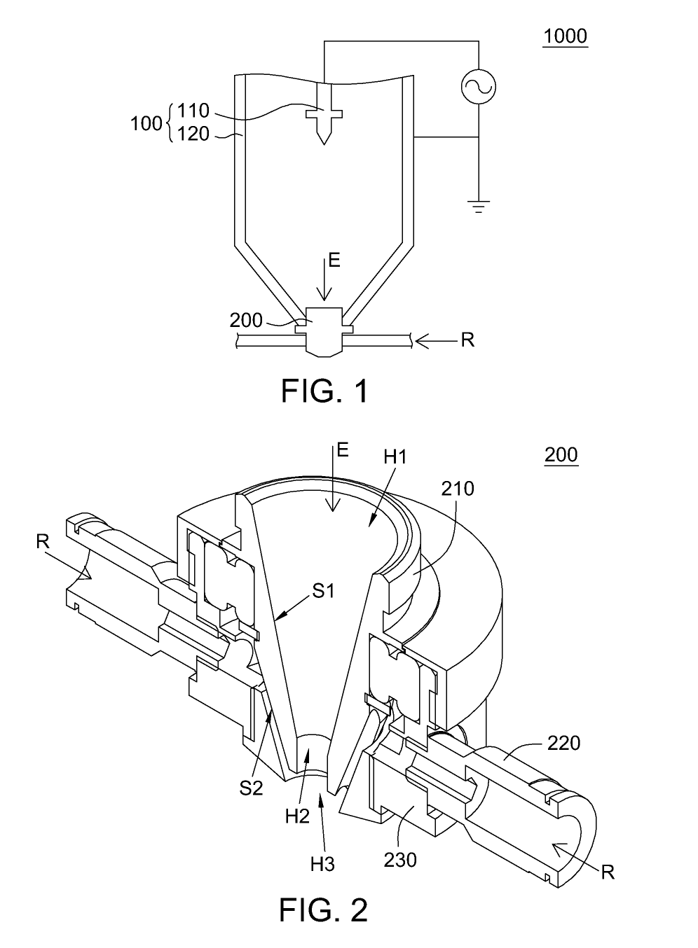

Referring to FIG. 1, a schematic diagram of a plasma system 1000 according to an embodiment of the invention is shown. The plasma system 1000 of the embodiment can be applied to surface activation, clearance, etching and film deposition. In the embodiment, the plasma system 1000 is exemplified to be applied in a film-deposition process. The plasma system 1000 includes a plasma cavity 100 and an injection device 200. The plasma cavity 100 is, for example, a vacuum cavity or an atmospheric-pressure cavity. The plasma system 1000 of the embodiment can be applied to a vacuum process or an atmospheric-pressure process. In the embodiment, the plasma cavity 100 is exemplified to be applied in the atmospheric-pressure process for illustration. The plasma cavity 100 is for generating a plasma E. The injection device 200 is connected to the plasma cavity 100 for injecting a reactant R. When the plasma system 1000 is applied in a film-deposition process, the reactant is a gas or nebulized liquid including the film material for instance. The reactant R is guided into the injection device 200 via a carrier gas. The reactant R can also be named as a film-forming monomer or precursor. Through the injection device 200, the plasma E can be mixed with the reactant R.

The plasma cavity 100 includes a first electrode 110 and a second electrode 120. A voltage drop is generated across the first electrode 110 and the second electrode 120 to ionize the gas of the plasma cavity 100 into the plasma E. The first electrode 110 and the second electrode 120 can be respectively a positive electrode and a ground electrode.

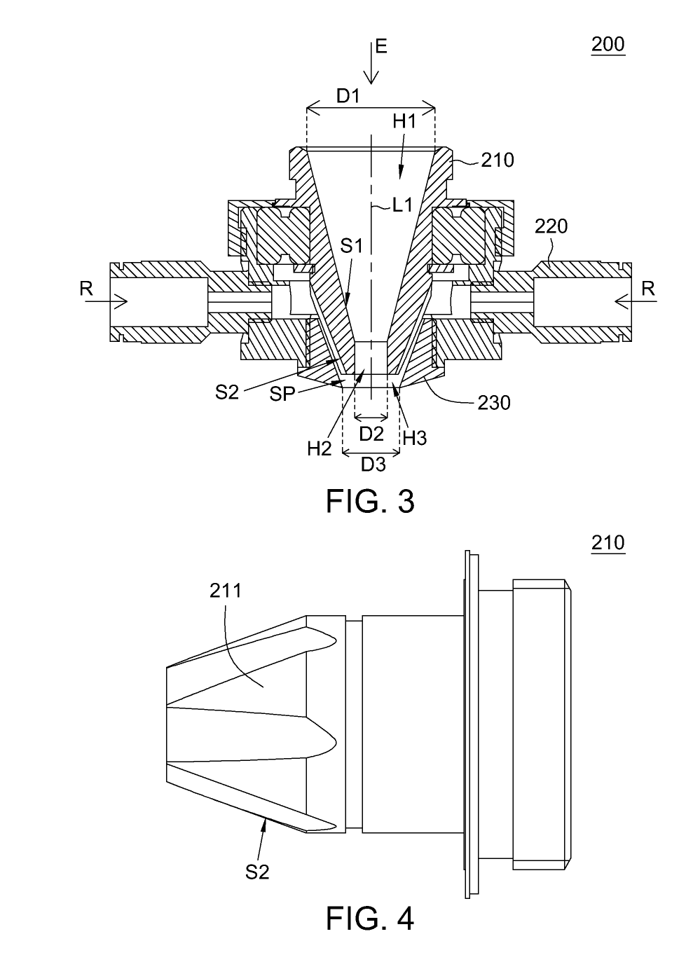

Referring to FIGS. 2 and 3, a cross-sectional solid view and a cross-sectional plan view of the injection device 200 in FIG. 1 are respectively shown. The injection device 200 includes a plasma injection tube 210, at least a reactant injection tube 220 and a cover body 230. The plasma injection tube 210 is connected to the plasma cavity 100 shown in FIG. 1. The plasma injection tube 210 includes an inlet H1, an outlet H2, an inner sidewall S1 and an outer sidewall S2. The plasma injection tube 210 injects the plasma E via the inlet H1 and guides the plasma E out through the outlet H2. The reactant injection tube 220 is disposed outside the outer sidewall S2. In the embodiment, two reactant injection tubes 220 are disposed in the injection device 200 for injecting two kinds of reactant R. In another embodiment, more than two injection tubes 220 can be used to inject more than two kinds of reactant R. The cover body 230 is connected to the reactant injection tube 220 and the cover body 230 has an opening H3, which is deposed at a position corresponding to the outlet H2.

As shown in FIG. 3, the plasma injection tube 210 of the embodiment is made of metal and electrically connected to the second electrode 120 shown in FIG. 1 so that the plasma injection tube 210 can have an inner space used for generating the plasma E. The inner sidewall S1 of the plasma injection tube 210 has a width decreasing from the inlet H1 to the outlet H2, i.e. the diameter D1 of the inlet H1 is larger than the diameter D2 of the outlet H2. Therefore, when the plasma E is guided out of the outlet H2, the flowing speed of the plasma E can be increased. Besides, the outer sidewall S2 of the plasma injection tube 210 has also a width decreasing from the inlet H1 to the outlet H2. That is, the plasma injection tube 210 is just like a cone structure.

As shown in FIG. 3, the reactant injection tube 220 is used for injecting the reactant R to the outer sidewall S2. Because the outer sidewall S2 of the plasma injection tube 210 has a width decreasing from the inlet H1 to the outlet H2, when the reactant R is injected to the outer sidewall S2, the reactant R can naturally flow toward the outlet H2 along the outer sidewall S2.

Moreover, the reactant injection tube 220 of the embodiment is substantially vertical to a line L1 connecting the inlet H1 and the outlet H2. The outer sidewall S2 has a tilt to the connection line L1 of the inlet H1 and the outlet H2, and thus the outer sidewall S2 has also a tilt to the reactant injection tube 220. For this reason, the reactant injection tube 220 can smoothly guides the reactant R to flow toward the outlet H2 along the outer sidewall S2.

As shown in FIG. 3, the cover body 230 is disposed at the outlet H2 of the plasma injection tube 210 and forms a mixture space SP at the outlet H2. After flowing to the outlet H2 along the outer sidewall S2, the reactant R can fully mix with the plasma E in the mixture space SP. Further, in order that the opening H3 of the cover body 230 can jet out the mixed reactant R and plasma E, the diameter D3 of the opening H3 in the embodiment is designed to be larger than the diameter D2 of the outlet H2. The cover body 230 and the reactant injection tube 220 can be two separate structural pieces or a structure integrated into a unity as needed.

In the embodiment, the plasma E and reactant R mix together in the mixture space SP outside of the plasma injection tube 210. The first electrode 110 and the second electrode 120 are disposed in the plasma cavity 100 so that the first electrode 110 and the second electrode 120 do not contact with the reactant R. Therefore, the reactant R is not deposited on the first electrode 110 or the second electrode 120, which not only increases the stability of the plasma E but also prevents contamination to the following process.

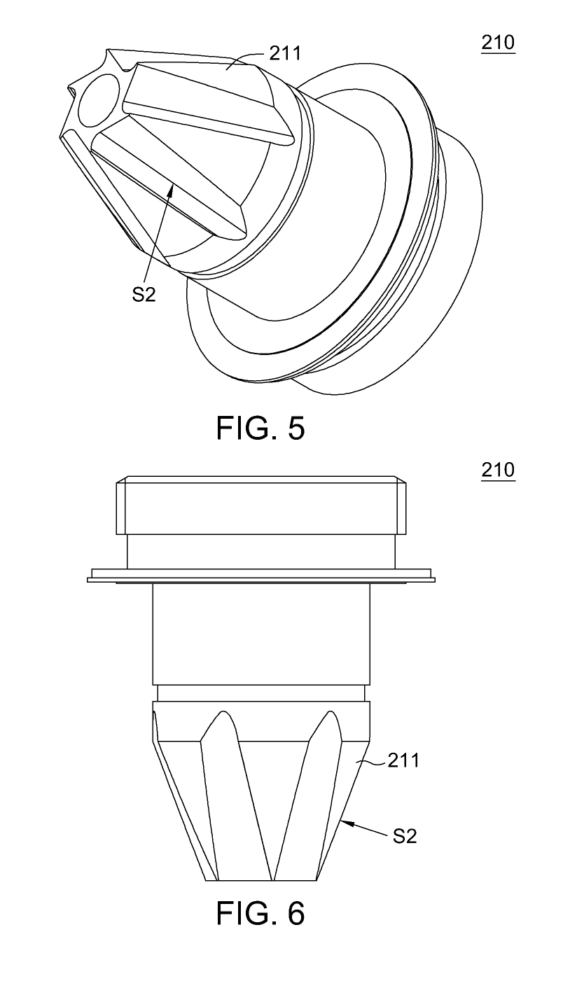

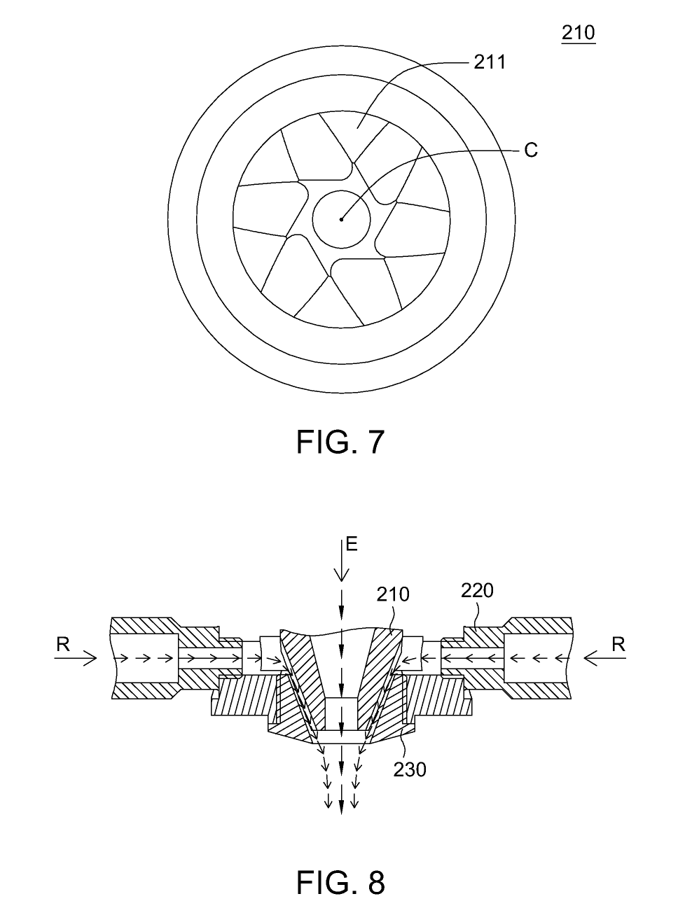

Referring FIGS. 4-6, solid views of the plasma injection tube 210 of FIG. 1 are shown. The plasma injection tube 210 of the embodiment is rotatably connected to the plasma cavity 100 shown in FIG. 1. The outer sidewall S2 of the plasma injection tube 210 has six fins 211. Referring to FIG. 7, a bottom view of the plasma injection tube 210 of FIG. 6 is shown. The fins 211 are disposed slightly apart from a central point C of the plasma injection tube 210. Therefore, when the reactant R, as shown in FIG. 3, gets to the outer sidewall S2 and pushes the fins 211, the fins 211 drive the plasma injection tube 210 to rotate so that the reactant R successively guided in can rotate along with the plasma injection tube 210. As such, the reactant R can flow toward the outlet H2 along the outer sidewall S2 in a swirl way.

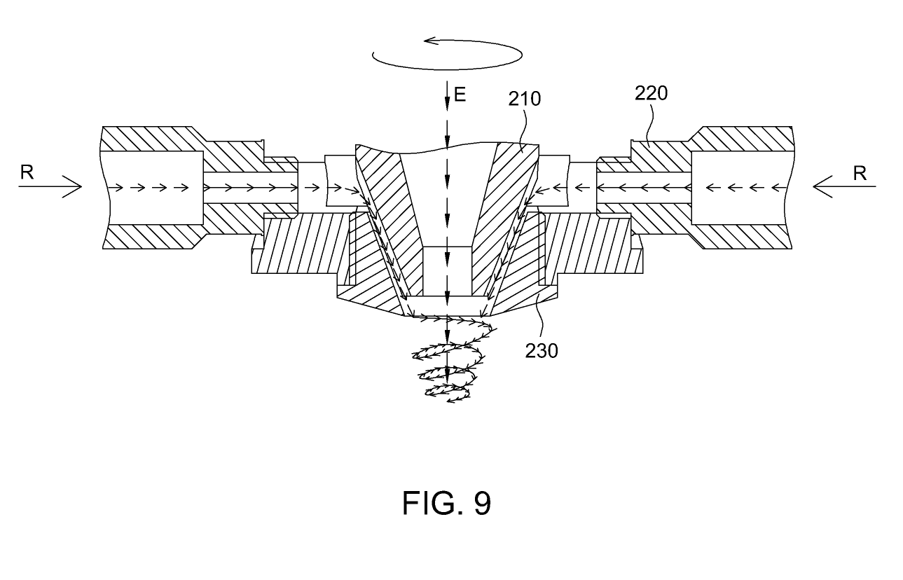

Referring to FIGS. 8-9, schematic diagrams of the plasma E and reactant R mixed in the plasma injection tube 210 under rotating and non-rotating conditions are respectively shown. As shown in FIG. 8, under the non-rotating condition of the plasma injection tube 210, the plasma E and reactant R are jetted downward almost in parallel. As shown in FIG. 9, under the rotating condition of the plasma injection tube 210, the reactant R accumulates towards the center and rotates around the plasma E. From the comparison between FIGS. 8 and 9, it can be known that when the reactant R accumulates to the center and rotates around the plasma E, the plasma E and reactant R have longer reaction time and better mixture state, thereby increasing the deposition rate.

The plasma injection tube 210 disclosed by the above embodiment can automatically rotate as the reactant R gets to the outer sidewall S2 to push the fins 211. However, in another embodiment, the plasma system 1000 can further include an electric power source, such as a motor, connected to the plasma injection tube 210 for driving the plasma injection tube 210 to rotate. Therefore, the plasma injection tube 210 can actively take the reactant R to flow toward the outlet H2 in a swirl way.

Besides, the reactant injection tubes 220 of the embodiment are disposed symmetric to the plasma injection tube 210. By this design, injecting the reactant R via the reactant injection tube 220 with different flow amount or speed can also drive the fins 221 to rotate without need of the above power source. In another embodiment, the reactant injection tubes 220 can also be designed slightly unsymmetrical to the plasma injection tube 210 so that the reactant R can more easily push the fins 221 to increase the rotation speed of the plasma injection tube 210.

In some embodiments, two or three of the above designs of power source, different reactant flowing amount/speed or unsymmetrical reactant injection tubes 220 can be adopted simultaneously as needed.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A plasma system, comprising:
a plasma cavity, comprising:
a first electrode and a second electrode, for generating a plasma; and
an injection device, comprising:
a plasma injection tube, connected to the plasma cavity, wherein the plasma injection tube comprises an inlet, an outlet and an outer sidewall, the plasma injection tube injects the plasma from the inlet and guides the plasma out through the outlet, and the outer sidewall has a width decreasing from the inlet to the outlet; and
at least a reactant injection tube, disposed outside of the outer sidewall, wherein the reactant injection tube injects a reactant to the outer sidewall so that the reactant flows along the outer sidewall toward the outlet and mixes with the plasma at the outlet.

2. The plasma system according to claim 1, wherein the outer sidewall has a plurality of fins for driving the reactant to rotate.

3. The plasma system according to claim 1, wherein the plasma injection tube is rotatably connected to the plasma cavity.

4. The plasma system according to claim 1, wherein the diameter of the inlet is larger than the diameter of the outlet.

5. The plasma system according to claim 1, wherein the plasma injection tube is electrically connected to the second electrode.

6. The plasma system according to claim 1, wherein the reactant injection tube is substantially vertical to a connection line of the inlet and the outlet.

7. The plasma system according to claim 1, wherein the injection device further comprises:
a cover body, connected to the reactant injection tube and comprising an opening, wherein the opening is disposed at a position corresponding to the outlet.

8. The plasma system according to claim 7, wherein the diameter of the opening is larger than the diameter of the outlet.
